(19) United States
(12) Patent Application Publication
(10) Pub. No.: US 2005/0037587 A1
(43) Pub. Date: Feb. 17, 2005

(54) Heterojunction bipolar transistor

(75) Inventors: Bertrand Martinet, Grenoble (FR); Michel Marty, Saint Paul De Varces (FR); Pascal Chevalier, Chapareillan (FR); Alain Chantre, Seyssins (FR)

Correspondence Address: James H. Morris;Wolf, Greenfield & Sacks, P.C., 600 Atlantic Avenue, Boston, MA, 02210-2206, US

(73) Assignee: STMicroelectronics S.A., Montrouge (FR)

(21) Appl. No.: 10/914,482

(22) Filed: Aug. 9, 2004

(30) Foreign Application Priority Data
Aug. 11, 2003 (FR) 03/50418

(51) Int. Cl. H01L 21/331; H01L 21/8222

(52) U.S. Cl. 438/309

(57) ABSTRACT

A method for forming a heterojunction bipolar transistor including the steps of: forming in a semiconductor substrate a collector area of a first doping type; growing by epitaxy above a portion of the collector area a silicon/germanium layer of a second doping type forming a base area; forming above the silicon/germanium layer a sacrificial emitter formed of a material selectively etchable with respect to the silicon/germanium layer and with respect to the layers and consecutively-formed insulating spacers; forming first insulating spacers on the sides of the sacrificial emitter; growing by epitaxy a silicon layer above the exposed portions of the silicon/germanium layer; forming second insulating spacers adjacent to the first spacers and laid on the silicon layer; covering the entire structure with an insulating layer; partially removing the insulating layer above the sacrificial emitter and removing the sacrificial emitter; filling the space previously taken up by the sacrificial emitter with a semiconductor material of the first doping type.

### BACKGROUND OF THE INVENTION

1. Field of the Invention

The present invention relates to bipolar transistor manufacturing methods using a sacrificial emitter as well as specific structures of transistors obtained according to such methods.

2. Discussion of the Related Art

U.S. Pat. No. 6,534,372 describes a method for manufacturing bipolar transistors with a heterojunction using a sacrificial emitter. This method is described hereafter in relation with FIGS. 1 and 2. An N-type collector area 1 is formed in a semiconductor substrate. A silicon/germanium layer 2 is grown by epitaxy above a portion of the collector area. Silicon/germanium layer 2 is P-type doped in situ and forms a base area. The base area is then covered with an “etch stop” insulating layer 3, a polysilicon layer 4, and a protection layer 5. The polysilicon and protection layers are then etched according to a first mask M1 to form a sacrificial emitter 6 laid on insulating layer 3. Insulating spacers 7 and 8 are formed on the sides of sacrificial emitter 6. The exposed portions of the insulating “etch stop” layer are etched. A strong ion implantation of the exposed portions of the silicon/germanium layer forming the base access areas is performed. The structure shown in FIG. 1 is then obtained. The entire structure is then covered with a second insulating layer 10 and with a resin layer. The resin is insolated through a second mask M2 to remove, after development, a resin portion located above the sacrificial emitter and above part of the spacers located close to the sacrificial emitter. The protection layer of the sacrificial emitter is then removed to etch the sacrificial emitter as well as the portion of the first insulating layer located under the sacrificial emitter. A polysilicon deposition is then performed to form an N-type emitter 11.

To overcome the possible misalignments of masks M1 and M2, it is necessary for the spacers to be wide enough to avoid that the base silicon/germanium layer is exposed at the end of the etching of insulating layer 10 performed according to mask M2. This is necessary to avoid any short-circuit between the emitter and the base access areas. The width of the base connection portions located under the spacers is defined according to the maximum possible offset between masks M1 and M2. The connection portions are accordingly relatively long. Further, their doping is relatively light and substantially identical to that of the “intrinsic” portion of the base located above the emitter. Accordingly, the connection portions exhibit a significant resistivity which significantly increases the base access resistance.

According to one of the embodiments of the method described in the above-mentioned US patent, it is provided to perform an implantation of the silicon/germanium layer after forming of the sacrificial emitter and before forming of the spacers so that the base connection portions are more heavily doped. This solution however exhibits a disadvantage, since in steps for which the temperature is high, the dopants slightly diffuse into the intrinsic base portion, which results in increasing the bipolar transistor leakage current.

Further, the ion implantation of the base silicon/germanium layer results in generating defects, gaps/openings, which tend to diffuse into the intrinsic base portion, which results in reducing the operating frequency of the bipolar transistor.

### SUMMARY OF THE INVENTION

An object of the present invention is to provide a bipolar transistor with a heterojunction exhibiting a very small resistance of access to the intrinsic portion of its base.

An object of the present invention is to provide such a transistor exhibiting a very small leakage current.

Another object of the present invention is to provide such a transistor exhibiting a high operating frequency.

An object of the present invention is to provide a method for manufacturing a heterojunction bipolar transistor exhibiting a very small resistance of access to the intrinsic portion of its base.

Another object of the present invention is to provide such a method that comprises no step of ion implantation of the base connection portions and of the base access areas.

To achieve these and other objects, the present invention provides a method for forming a heterojunction bipolar transistor comprising: forming, in a semiconductor substrate, a collector area of a first doping type; growing by epitaxy above a portion of the collector area a silicon/germanium layer of a second doping type forming a base area; forming above the silicon/germanium layer a sacrificial emitter formed of a material selectively etchable with respect to the silicon/germanium layer and with respect to the consecutively-formed layers and insulating spacers; forming first insulating spacers on the sides of the sacrificial emitter; growing by epitaxy a silicon layer above the exposed portions of the silicon/germanium layer; forming second insulating spacers adjacent to the first spacers and laid on the silicon layer; covering the entire structure with an insulating layer; partially removing the insulating layer above the sacrificial emitter and removing the sacrificial emitter; filling the space previously taken up by the sacrificial emitter with a semiconductor material of the first doping type.

According to an embodiment of the above-described method, the sacrificial emitter is a trilayer formed of an insulating etch stop insulating layer, of a polysilicon layer, and of a protection layer.

According to an embodiment of the above-described method, the method comprises oxidation of the silicon/germanium layer prior to the step of forming a sacrificial emitter, the oxide portions covered neither by the sacrificial emitter, nor by the first spacers being etched prior to the step of epitaxial growth of a silicon layer.

According to an embodiment of the above-described method, the silicon/germanium layer and the silicon layer are doped during their epitaxial growth.

According to an embodiment of the above-described method, said insulating layer is formed of silicon oxide and the first and second insulating spacers are formed of nitride.

According to an embodiment of the above-described method, said insulating layer and each of the first and second insulating spacers are formed of a silicon oxide layer and of a nitride layer.

According to an embodiment of the above-described method, the method further comprises etching said semiconductor material on either side of the second spacers to expose given portions of the silicon/germanium layer.

The present invention also provides a bipolar transistor with a heterojunction comprising a collector of a first doping type formed in a silicon substrate, a base formed of a silicon/germanium layer of a second doping type covering the collector, and an emitter comprising a central silicon portion of the first doping type laid on a portion of the base, first insulating spacers being adjacent to the sides of the central portion of the emitter and laid on the silicon/germanium layer, portions of the base covered neither by the central portion of the emitter nor by the spacers being covered with a silicon layer of the second doping type, second insulating spacers being adjacent to the first spacers and laid on the silicon layer, the second spacers and the silicon layer being covered at least partially with an insulating layer, the portions in contact of the insulating layer and of the second spacers being formed of different insulators, the emitter prolonging in lateral extensions, above the first and second spacers and the insulating layer.

According to an embodiment of the above-described transistor, said silicon layer is covered with a silicide layer.

According to an embodiment of the above-described transistor, said insulating layer is formed of silicon oxide and the first and second spacers are formed of nitride.

The foregoing objects, features, and advantages of the present invention will be discussed in detail in the following non-limiting description of specific embodiments in connection with the accompanying drawings.

### BRIEF DESCRIPTION OF THE DRAWINGS

FIGS. 1 and 2 are cross-section views of structures obtained after successive steps of a method according to prior art;

FIG. 3 is a perspective view of a bipolar transistor with a heterojunction according to the present invention; and

FIGS. 4 to 10 are cross-section views of structures obtained after successive steps of the method of the present invention.

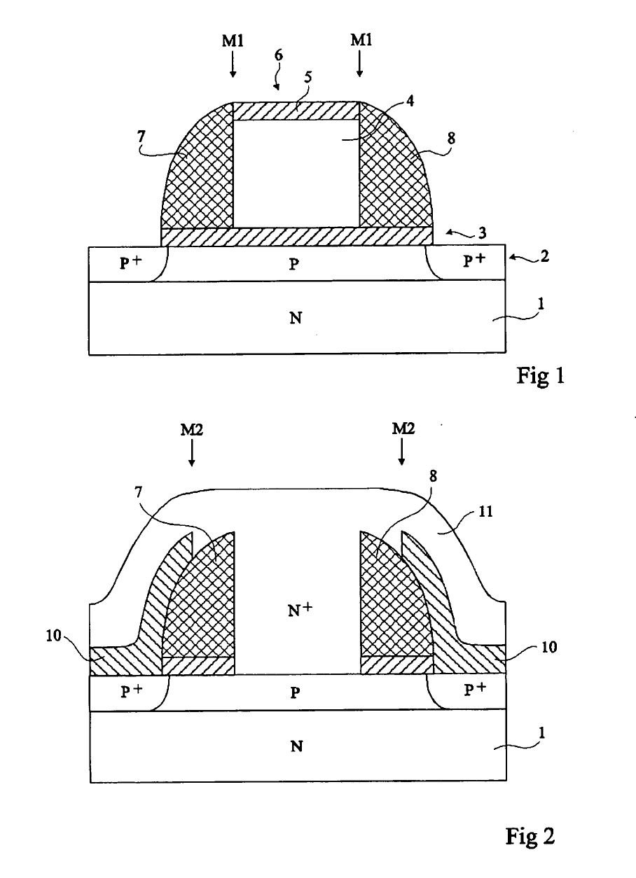

### DETAILED DESCRITPION

For clarity, the same elements have been designated with the same reference numerals in the different drawings and, further, as usual in the representation of integrated circuits, the drawings are not to scale.

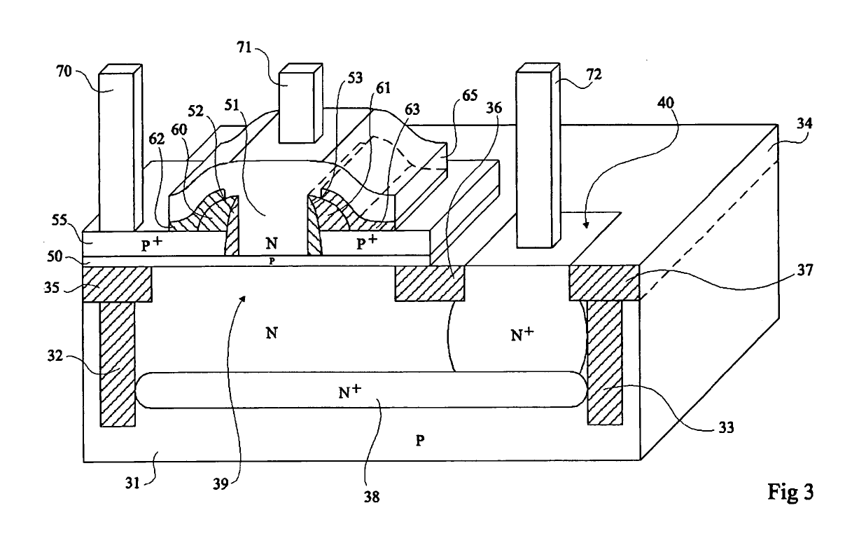

FIG. 3 is an example of an NPN bipolar transistor with a heterojunction according to the present invention formed in and above a silicon substrate 31. Two portions 32 and 33 of a deep insulation area are visible respectively to the left and to the right of the cross-section plane of substrate 31. A shallow insulation area 34 is formed at the surface of substrate 31. Three portions 35, 36, and 37 of insulation area 34 are visible in the cross-section plane of substrate 31 respectively from left to right. Portions 35 and 37 are respectively placed above portions 32 and 33 of the deep insulation area. A heavily-doped N-type buried layer 38 is placed in substrate 31 at the bottom of a portion of substrate 31 of substantially parallelepipedal shape delimited by the deep insulation area. Portions 35 and 36 of insulation area 34 surround the top of an upper area 39 of substrate 31. Portions 36 and 37 of insulation area 34 surround the top of an upper area 40 of substrate 31. Areas 36 and 37 have in top view a substantially rectangular shape. Upper area 39 placed above buried layer 38 is N-type doped and forms the collector of the bipolar transistor. Upper area 40 placed above buried layer 38 is heavily N-type doped and forms a collector well. The substrate area placed under the buried layer is lightly P-type doped.

A silicon silicon/germanium layer 50 covers collector area 39 as well as portion 35 and the left-hand portion of portion 36 of insulation area 34. Silicon/germanium 50 is P-type doped and forms the base of the bipolar transistor. A polysilicon portion 51 of substantially parallelepipedal shape is laid on base layer 50 above collector area 39. Silicon portion 51 is heavily N-type doped and forms the emitter of the bipolar transistor. Insulating spacers 52 and 53 are adjacent to the sides of emitter portion 51 and are laid on base layer 50. The portions of base layer 50 covered neither by emitter portion 51, nor by spacers 52 and 53 are covered with a heavily-doped P-type silicon layer 55. Insulating spacers 60 and 61 are adjacent to spacers 52 and 53 and rest on silicon layer 55. Insulating layers 62 and 63 cover the low portions of spacers 60 and 61 as well as a portion of silicon layer 55. A silicon layer 65 covers emitter portion 51, the high portions of spacers 52 and 53, 60 and 61 as well as insulating layers 62 and 63. Silicon layer 65 is heavily N-type doped like silicon portion 51, layer 65, and silicon portion 51 forming the transistor emitter. Contacts 70, 71, and 72 are respectively laid above the left-hand portion of silicon layer 55, above portion 35 of insulation area 34, above silicon emitter layer 65, and above collector well area 40.

According to an aspect of the present invention, spacers 52 and 53, 60 and 61 are formed of an insulator different from that of insulating layers 62 and 63. Spacers 52 and 53, 60 and 61 are for example formed of nitride and insulating layers 62 and 63 are formed of silicon oxide. However, each of the spacers and each of the insulating layers may be formed of several insulators. In this case, portions of spacers 52 and 53, 60 and 61 in contact with the portions of insulating layers 62 and 63 must be formed of different insulators.

The portion of silicon/germanium layer 50 located above emitter portion 51 forms the “intrinsic” portion of the base through which a strong current from the emitter to the collector can flow. The portions of layer 50 located under spacers 52 and 53 form the base connection portions. Heavily-doped silicon portion 55 and the portions of layer 50 located under layer 55 form contact portions or “extrinsic” portions of the base.

The bipolar transistor of the present invention differs from known transistors especially by the presence of two spacer levels. The first level is formed of spacers 52 and 53, the second level is formed of spacers 60 and 61. The first spacer level is preferably very narrow so that the length of the base connection portions is as small as possible, which enables strongly reducing the resistance of access to the intrinsic portion of the transistor base. The second spacer level may also be as wide as desired.

The intrinsic portion is relatively lightly doped to limit the leakage current of the transistor. Silicon layer 55 being heavily doped, the resistance of the “extrinsic” portion is very low. Further, close to silicon layer 55, layer 50 is more heavily doped, strongly-concentrated dopants tending to diffuse. Accordingly, the base connection portions have a smaller resistivity.

An advantage of a bipolar transistor according to the present invention is that the connection portions have a smaller length and a lower resistivity than the portions of connection of the bipolar transistor described in the above-mentioned patent.

The bipolar transistor according to the present invention is likely to have various alternatives and modifications which will readily occur to those skilled in the art. In particular, the collector area and the areas of access to the collector may have various shapes. Further, the upper part of silicon layer 55 may be silicided to increase the conductivity of this layer. Further, it will be within the abilities of those skilled in the art to form a PNP bipolar transistor having a structure similar to that of the previously-described NPN transistor.

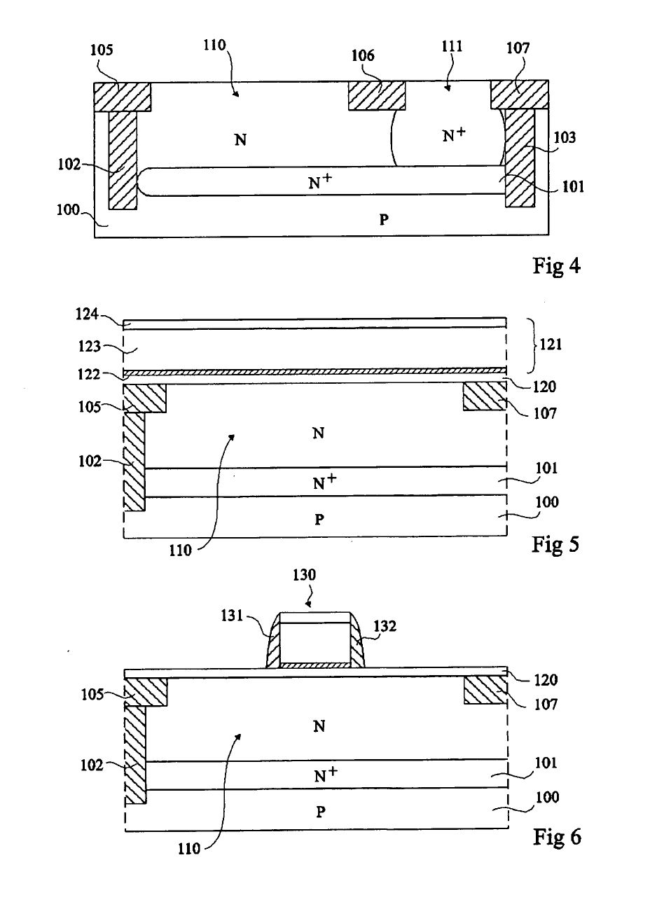

The bipolar transistor described in relation with FIG. 3 can be obtained according to the present invention with a method such as that described hereafter in relation with FIGS. 4 to 10.

In an initial step, a collector and accesses to this collector having in this example shapes identical to those of the corresponding elements of the transistor shown in FIG. 3 are formed in a substrate 100, conventionally, silicon. An N+ buried layer 101 is surrounded with a deep insulation layer having two portions 102 and 103 shown respectively to the left and to the right of the cross-section view. Three portions 105, 106, and 107 of a shallow insulation layer are visible at the surface of the substrate respectively from left to right. Portions 105 and 107 are placed above portions 102 and 103 of the shallow insulation area. A substrate area 110, placed above buried layer 101 and emerging between portions 105 and 106, is N-type doped and forms the future collector of the transistor. A substrate area 111, placed above buried layer 101 and emerging between portions 106 and 107, is heavily N-type doped and forms the future collector bridge of the transistor. The portion of substrate 100 located under buried layer 101 is P-type doped.

In the following description, the forming of the bipolar transistor above collector area 110 will be considered. Thus, only the left-hand portion of the structure shown in FIG. 4 will be shown in the next drawings.

At the next step, illustrated in FIG. 5, a silicon/germanium layer 120 is grown by non-selective epitaxy above collector area 110 and portions 105 and 106 of a shallow insulation area. The portions of silicon/germanium layer 120 placed above collector area 110 are single-crystal portions, those placed above portions 105 and 106 are polycrystalline portions. Silicon/germanium layer 120 may be P-type doped, for example, during its epitaxial growth. The germanium proportion may be progressively reduced during the epitaxial growth of the silicon/germanium layer, as conventional.

A “sacrificial” layer 121 formed in this example of a stacking of three layers, an “etch stop” insulating layer 122, a polysilicon layer 123, and a protection layer 124 formed in this example of silicon oxide, are then formed. Generally, the sacrificial layer will have to be formed of a material selectively etchable with respect to silicon/germanium layer 120 and with respect to the layers and insulating spacers formed in the next steps. Protection layer 124, although optional, enables simplifying the method as will appear hereafter.

At the next step, illustrated in FIG. 6, sacrificial layer 121 is etched to form a sacrificial emitter 130 having in this cross-section view a substantially rectangular shape.

Insulating spacers 131 and 132 are then formed on the sides of sacrificial emitter 130. A conventional method for forming insulating spacers for example consists of performing a conformal nitride deposition over the entire structure and of then performing an anisotropic etch of the nitride layer.

According to an alternative of the method of the present invention, the order of the operations of the step illustrated in FIG. 6 may be slightly modified. It may be provided to etch protection layer 124 and polysilicon layer 123, then to form spacers and then remove the exposed portions of insulating layer 122. In this case, small portions of insulating layer 122 are present under spacers 131 and 132.

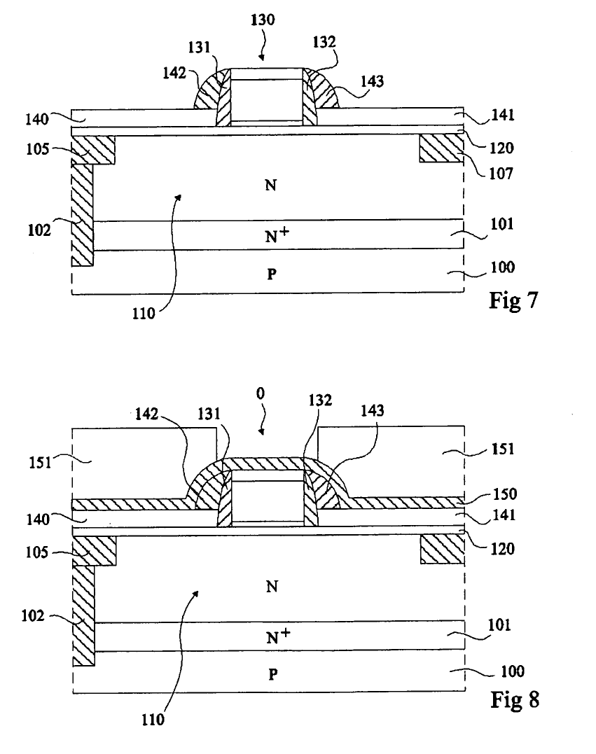

At the next step, illustrated in FIG. 7, a silicon layer is grown by epitaxy above the exposed portions of silicon/germanium layer 120. The silicon layer may be heavily P-type doped during its epitaxial growth. In this cross-section view, two portions 140 and 141 of the silicon layer are visible. Sacrificial emitter 123 being in this example formed of silicon, the presence of a protection layer avoids for a silicon “boule” to form by epitaxy above the sacrificial emitter. Too thick a boule could adversely affect the proper progress of the next steps.

Insulating spacers 142 and 143 adjacent to spacers 131 and 132 and laid on the silicon layer, respectively, on portions 140 and 141, are then formed. The spacers may be formed according to a method identical to that described for spacers 131 and 132.

According to an embodiment of the method of the present invention, spacers 131, 132 and/or spacers 142, 143 may be formed according to a method consisting of forming a thin silicon oxide layer and of covering it with a nitride layer and finally of removing the portions of the thin silicon oxide layer non covered by the remaining portions of the nitride layer. The etching of the nitride by using as a stop layer a silicon oxide layer is indeed easier than by using a silicon layer as a stop layer.

At the next step, illustrated in FIG. 8, the entire previously-obtained structure is covered with an insulating layer 150. Layer 150 will have to be formed of an insulator different from that of spacers 131, 132, 142, and 143. More specifically, insulating layer 150 must be selectively etchable with respect to spacers 131, 132, 142, and 143.

Insulating layer 150 is then covered with a resin layer 151 which is insolated to obtain after development an opening 0 of the resin above the sacrificial emitter and above the high portion of spacers 131, 132, 142, and 143.

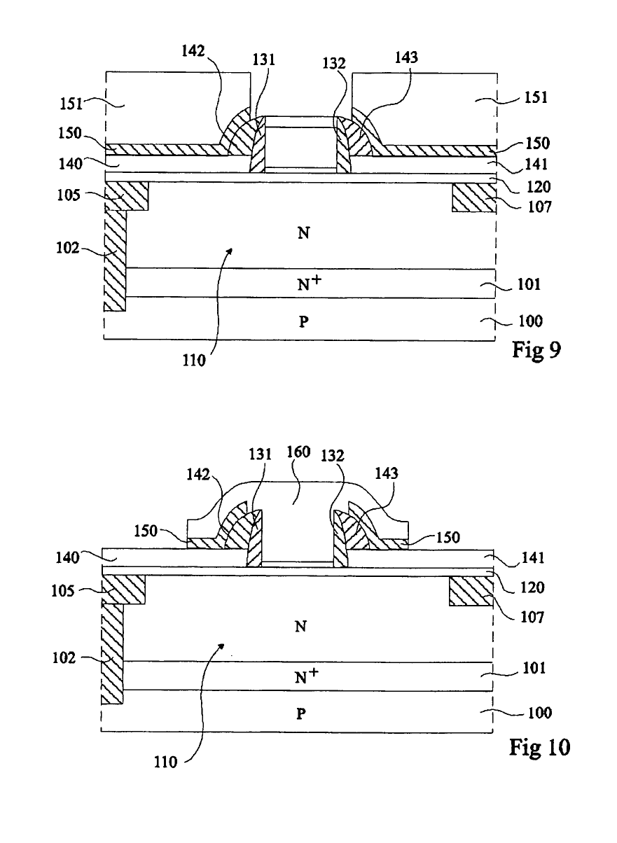

At the next step, illustrated in FIG. 9, the portion of insulating layer 150 non protected by resin 151 is removed, after which the sacrificial emitter is removed by performing in this example three consecutive etches of the remaining portions of protection layer 124, of polysilicon layer 123, and of insulating layer 122. Resin layer 151 is then removed.

At the next step, illustrated in FIG. 10, the entire structure is covered with a semiconductor material such as polysilicon. This semiconductor layer is doped, for example, of type N upon deposition thereof, or by a subsequent implantation. Semiconductor layer 160 and insulating layer 150 are then etched to expose parts of portions 140 and 141 of the silicon layer to be able to form in a subsequent step contacts enabling access to the silicon layer forming an area of access to the transistor base.

In the previously-described method, two steps implement a photolithography method using a mask to define on the one hand the sacrificial emitter and on the other hand opening O of resin 151 above the sacrificial emitter. The size of opening O will be provided to be greater than the upper surface of the sacrificial emitter to take into account the possible offset of the two masks. The maximum offset of the two masks must preferably be provided so that the entire upper surface of the sacrificial emitter is exposed after etching of insulating layer 150 to properly remove the sacrificial emitter and to properly fill the emptied space to form the definitive emitter. The width of spacers 131 and 132 may be chosen to be as small as possible given that spacers 142 and 143 enable protecting silicon layers 140 and 141 and thus avoid for a strong offset of the two masks to result in fine in a short-circuit between the emitter and the transistor base.

An advantage of the method of the present invention is that it enables choosing the width of spacers 131 and 132 independently from the maximum offset value between the two etch masks. The length of the connection portions may thus be made as small as possible, which enables reducing the resistance of access to the transistor base.

After the previously-described steps, one or several steps for which the structure is placed in a high temperature chamber are provided. During these steps, the dopants present in the semiconductor areas tend to diffuse and this, all the more as the dopant concentration is high. Thus, N-type dopants diffuse slightly from the emitter to the base and P-type dopants diffuse portions 140 and 141 of the silicon layer towards base silicon/germanium layer 120. Further, P-type dopants diffuse into the connection portion of silicon/germanium layer 120 located under spacers 131 and 132. It will be within the abilities of those skilled in the art to define the adequate width of spacers 131 and 132 enabling a diffusion of dopants P into the connection portion to above the emitter walls without for them to diffuse under the emitter. The transistor base access resistance can thus be strongly reduced without increasing the leakage current of the transistor, conversely to the method described in the above mentioned US patent.

Further, the method of the present invention comprises no step of implantation of silicon/germanium layer 120, which enables avoiding introduction of defects into this 10 layer. Another advantage of the method of the present invention thus is that it enables forming bipolar transistors operating at higher frequencies.

Although this has not been described in the above-mentioned method, a step of silicidation of portions 140 and 141 of the silicon layer may be carried out just after their forming. The forming of a silicide layer at the surface of portions 140 and 141 enables strongly reducing their resistances. The silicidation of a silicon layer provides silicides of better quality than silicides obtained upon silicidation of a silicon/germanium layer. Accordingly, this enables further decreasing the transistor base access resistance comparatively to the transistor described in the above-mentioned US patent.

The method according to the present invention is likely to have various alterations, modifications, and improvements which will readily occur to those skilled in the art. In particular, it will be within the abilities of those skilled in the art to define an equivalent PNP bipolar transistor forming method.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

1. A method for forming a bipolar transistor with a heterojunction comprising:
forming in a semiconductor substrate a collector area of a first doping type;
growing by epitaxy above a portion of the collector area a silicon/germanium layer of a second doping type forming a base area;
forming above the silicon/germanium layer a sacrificial emitter formed of a material selectively etchable with respect to the silicon/germanium layer and with respect to the consecutively-formed layers and insulating spacers;
forming first insulating spacers on the sides of the sacrificial emitter;
growing by epitaxy a silicon layer above the exposed portions of the silicon/germanium layer;
forming second insulating spacers adjacent to the first spacers and laid on the silicon layer;
covering the entire structure with an insulating layer;
partially removing the insulating layer above the sacrificial emitter and removing the sacrificial emitter;
filling the space previously taken up by the sacrificial emitter with a semiconductor material of the first doping type.

2. The method of claim 1, wherein the sacrificial emitter is a trilayer formed of an insulating etch stop insulating layer, of a polysilicon layer, and of a protection layer.

3. The method of claim 2, comprising oxidizing the silicon/germanium layer prior to the step of forming a sacrificial emitter, the oxide portions covered neither by the sacrificial emitter, nor by the first spacers being etched prior to the step of epitaxial growth of a silicon layer.

4. The method of claim 1, wherein the silicon/germanium layer and the silicon layer are doped during their epitaxial growth.

5. The method of claim 1, wherein said insulating layer is formed of silicon oxide and the first and second insulating spacers are formed of nitride.

6. The method of claim 1, wherein said insulating layer and each of the first and second insulating spacers are formed of a silicon oxide layer and of a nitride layer.

7. The method of claim 1, further comprising etching said semiconductor material on either side of the second spacers to expose given portions of the silicon/germanium layer.

8. A heterojunction bipolar transistor comprising a collector of a first doping type formed in a silicon substrate, a base formed of a silicon/germanium layer of a second doping type covering the collector, and an emitter comprising a central silicon portion of the first doping type laid on a portion of the base, first insulating spacers being adjacent to the sides of the central portion of the emitter and laid on the silicon/germanium layer, portions of the base covered neither by the central portion of the emitter nor by the spacers being covered with a silicon layer of the second doping type, second insulating spacers being adjacent to the first spacers and laid on the silicon layer, the second spacers and the silicon layer being covered at least partially with an insulating layer, the portions in contact of the insulating layer and of the second spacers being formed of different insulators, the emitter prolonging in lateral extensions, above the first and second spacers and the insulating layer.

9. The transistor of claim 8, wherein said silicon layer is covered with a silicide layer.

10. The bipolar transistor of claim 9, wherein said insulating layer is formed of silicon oxide and the first and second spacers are formed of nitride.
